(19) United States
(12) Patent Application Publication
(10) Pub. No.: US 2026/0017423 A1
(43) Pub. Date: Jan. 15, 2026

(54) SYSTEM AND METHOD FOR CREATING DIGITAL TWIN

(71) Applicant: SIMACRO INC., Seoul (KR)

(72) Inventors: Jeong Ho YUN, Lexington, MA (US); Wang Soo KIM, Seoul (KR); Elijah PARK, Seoul (KR); Hyeon Jun JO, Seoul (KR)

(21) Appl. No.: 19/330,850

(22) Filed: Sep. 17, 2025

Related U.S. Application Data
(63) Continuation of application No. PCT/KR2024/000746, filed on Jan. 16, 2024.

(30) Foreign Application Priority Data
Mar. 17, 2023 (KR) 10-2023-0035333
Jul. 11, 2023 (KR) 10-2023-0089589

(51) Int. Cl. G06F 30/17

(52) U.S. Cl. CPC G06F 30/17

(57) ABSTRACT

Provided are a system and method for creating a digital twin. The method performed by at least one processor includes receiving, by the processor, plant data generated by sensing a target facility which is a target of a digital twin, determining, by the processor, whether the plant data is in a steady state on the basis of the plant data, when the plant data is in a steady state, updating, by the processor, parameters of a prediction model on the basis of the plant data, inputting, by the processor, the plant data into the prediction model based on the updated parameters to generate prediction data, and outputting, by the processor, the prediction data.

### CROSS-REFERENCE TO RELATED APPLICATION

This application is a U.S. Bypass Continuation application of International Application No. PCT/KR2024/000746, filed on Jan. 16, 2024, which claims priority to and the benefit of Korean Patent Application No. 10-2023-0035333, filed on Mar. 17, 2023, and Korean Patent Application No. 10-2023-0089589, filed on Jul. 11, 2023, the disclosure of which is incorporated herein by reference in its entirety.

### BACKGROUND

### Technical Field

The present invention relates to a method of creating a digital twin, and more particularly, to a digital twin creation method of adaptively changing simulation parameters, and a digital twin creation system for performing the same.

### Discussion of Related Art

A digital twin refers to a technology for visualizing a physical system in a digital form using measurable data as if it were a twin. With a digital twin, not only measured data but also values calculated by simulation can be viewed directly in real time on a two-dimensional (2D) screen or through three-dimensional (3D) imagery. By digitizing and representing the key variables of a physical system, it is possible to analyze the current state of the system, predict future behavior, and even prevent potential hazards such as an explosion in a chemical process. Like this, digital twins are primarily used to effectively monitor, manage, and control systems and also utilized in factory design, construction, and optimization.

Digital visualization, a benefit of digital twins, has many advantages, especially in terms of monitoring, measurement, and control. One of the advantages is that it is possible to observe values that cannot be easily measured in a physical system (e.g., a temperature change over time inside food) along with result values obtained through simulation. This is especially useful when values that are not easily measured are important factors in determining a system's performance including efficiency and the like. In addition to monitoring systems, digital twins may help users manage and control their operations while observing changes in the process.

However, current digital twin technology utilizes a method of updating data received from facilities such as smart factories at regular intervals, and thus it is difficult to reflect the data in real time. Also, since a determined model is utilized to create a digital twin, it is difficult to reflect changes in facilities in the model.

### SUMMARY OF THE INVENTION

An object to be achieved by the technical spirit of the present disclosure is to provide a digital twin creation method of updating parameters using plant data in a steady state and creating a digital twin on the basis of the updated parameters, and a digital twin creation system for performing the same.

According to the technical spirit of the present disclosure, there is provided a digital twin creation method performed by at least one processor, the digital twin creation method including receiving, by the processor, plant data generated by sensing a target facility which is a target of a digital twin, determining, by the processor, whether the plant data is in a steady state on the basis of the plant data, when the plant data is in a steady state, updating, by the processor, parameters of a prediction model on the basis of the plant data, inputting, by the processor, the plant data into the prediction model based on the updated parameters to generate prediction data, and outputting, by the processor, the prediction data.

The determining of whether the plant data is in a steady state may include receiving a plurality of pieces of plant data that are sequentially measured over time during a first period, calculating a variance value of the plurality of pieces of plant data, determining whether the variance value is a predetermined value or less, and when the variance value is the predetermined value or less, determining that the plurality of pieces of plant data are in a steady state.

The updating of the parameters of the prediction model on the basis of the plant data may include calculating a mean value of the plurality of pieces of plant data, acquiring the parameters from the prediction model using the calculated mean value, and applying the acquired parameters to the prediction model to update the parameters.

The receiving of the plant data may include receiving the plant data every second period, which is shorter than the first period.

The updating of the parameters of the prediction model may include collecting the plurality of pieces of plant data by collecting N (N is a natural number of 2 or more) pieces of the plant data, which correspond to the first period, acquired every second period, calculating a mean value of the plurality of pieces of plant data, acquiring the parameters from the prediction model using the calculated average value, and updating the parameters by applying the acquired parameters to the prediction model.

The receiving of the plant data may include receiving a mean value of data sensed from the target facility at the second periods as the plant data.

The digital twin creation method may further include creating the digital twin by applying an interface corresponding to the prediction data to the target facility.

According to the technical spirit of the present disclosure, there is provided a digital twin creation system including a steady state determiner configured to determine whether plant data generated by sensing a target facility which is a target of a digital twin is in a steady state, a parameter updater configured to acquire parameters by applying the plant data to a prediction model when the plant data is in a steady state, and apply the acquired parameters to the prediction model, a prediction data generator configured to generate prediction data by inputting the plant data into the prediction model with the updated parameters, and an interface part configured to create a digital twin by interfacing with the digital twin on the basis of the prediction data.

The steady state determiner may determine whether a plurality of pieces of plant data that are sequentially measured over time during a first period are in a steady state on the basis of whether a variance value of the plurality of pieces of plant data is a predetermined value or less.

The parameter updater may acquire the parameters from the prediction model using a mean value of the plurality of pieces of plant data.

According to the present invention, a method of creating a digital twin performed by at least one processor, the method comprising: receiving, by the processor, plant data generated by sensing a target facility which is a target of a digital twin, the plant data being acquired at a second period that is shorter than a first period; determining, by the processor, whether the plant data is in a steady state based on the plant data, the determining comprising: receiving a plurality of pieces of the plant data that are sequentially measured over the first period, computing a variance value of the plurality of pieces of the plant data, determining whether the variance value is less than or equal to a predetermined value, and in response to the variance value being less than or equal to the predetermined value, determining that the plurality of pieces of the plant data are in the steady state; when the plant data is in the steady state, updating, by the processor, parameters of a prediction model based on the plant data, the updating comprising: calculating a mean value of the plurality of pieces of the plant data, acquiring parameters from the prediction model using the calculated mean value, and applying the acquired parameters to the prediction model; generating, by the processor, prediction data by inputting the plant data into the prediction model based on the updated parameters; outputting, by the processor, the prediction data; and creating, by the processor, the digital twin by applying an interface corresponding to the prediction data to a digital representation of the target facility.

The step of receiving the plant data may comprise receiving the plant data every second period, which is shorter than the first period.

The step of updating the parameter comprises collecting N (N is a natural number of 2 or more) pieces of the plant data corresponding to the first period and acquired every second period, calculating a mean value of the collected plant data, acquiring the parameters from the prediction model using the calculated mean value, and applying the acquired parameters to the prediction model.

The step of receiving the plant data comprises receiving, as the plant data, a mean value of data sensed from the target facility during each second period.

The step of creating the digital twin comprises interfacing the prediction data with the digital twin so that the prediction data is reflected in a visualization of the target facility.

### BRIEF DESCRIPTION OF THE DRAWINGS

The above and other objects, features, and advantages of the present invention will become more apparent to those of ordinary skill in the art by describing exemplary embodiments thereof in detail with reference to the accompanying drawings, in which:

FIG. 1 is a block diagram of a digital twin creation system according to an exemplary embodiment of the present disclosure;

FIG. 2 is a block diagram showing a digital twin creation server according to an exemplary embodiment of the present disclosure;

FIG. 3 is a flowchart showing a digital twin creation method according to an exemplary embodiment of the present disclosure;

FIG. 4 is a diagram showing a digital twin creation method according to the exemplary embodiment of the present disclosure;

FIG. 5 is a table showing a steady state determination method according to an exemplary embodiment of the present disclosure;

FIG. 6 is a flowchart showing the digital twin creation method according to the exemplary embodiment of the present disclosure;

FIG. 7 is a view of a digital twin according to an exemplary embodiment of the present disclosure; and

FIG. 8 is a block diagram showing a digital twin creation server according to an exemplary embodiment of the present disclosure.

### DETAILED DESCRIPTION OF EXEMPLARY EMBODIMENTS

A digital twin creation method performed by at least one processor includes receiving, by the processor, plant data generated by sensing a target facility which is a target of a digital twin, determining, by the processor, whether the plant data is in a steady state on the basis of the plant data, when the plant data is in a steady state, updating, by the processor, parameters of a prediction model on the basis of the plant data, inputting, by the processor, the plant data into the prediction model based on the updated parameters to generate prediction data, and outputting, by the processor, the prediction data.

Hereinafter, exemplary embodiments of the present disclosure will be described in detail with reference to the accompanying drawings. Advantages and features of the present invention and methods of achieving them will become apparent with reference to exemplary embodiments described in detail below in conjunction with the accompanying drawings. However, the technical spirit of the present disclosure is not limited to the embodiments disclosed below but may be implemented in various different forms, and the embodiments are only provided to make the technical spirit of the present disclosure complete and fully convey the scope of the present disclosure to those of ordinary skill in the art to which the present disclosure pertains. The technical scope of the present disclosure is only defined by the scope of claims.

When assigning reference numerals to components of each drawing, it is to be noted that the same components have the same reference numeral even if they are shown in different drawings. In addition, when describing the present disclosure, detailed description of related known components or functions will be omitted if it is deemed to obscure the subject matter of the present disclosure.

Unless otherwise defined, all terms used herein (including technical or scientific terms) may be used with the same meanings as commonly understood by those of ordinary skill in the technical field to which the present disclosure pertains. Terms such as those defined in commonly used dictionaries are not construed as having an idealized or unduly formal meaning unless expressly defined. Terminology used herein is intended to describe embodiments and is not intended to limit the present disclosure. In this specification, singular expressions include plural expressions unless context clearly indicates otherwise.

Also, in the description of components of the present disclosure, terms such as “first,” “second,” “A,” “B,” “(a),” “(b),” etc., may be used. These terms are used only for the purpose of discriminating one component from another component, and the nature, the sequence, the order, etc., of the components are not limited by the terms. It is to be noted that, when one component is described as being “connected,” “coupled,” or “joined” to another component, the former may be directly “connected,” “coupled,” or “joined” to the latter, or still another component may be “connected,” “coupled,” or “joined” between the components.

As used herein, the term “comprises” and/or “comprising” does not exclude the presence or addition of one or more components, steps, operations, and/or elements other than stated components, steps, operations, and/or elements.

Components included in one embodiment and components having a common function will be described using the same names in other embodiments. Unless otherwise described, the description of any one embodiment is applicable to other embodiments, and detailed descriptions may be omitted within the scope of overlap or the scope that can be readily understood by those skilled in the art.

Hereinafter, the present invention will be described in detail with reference to exemplary embodiments of the present invention and the accompanying drawings.

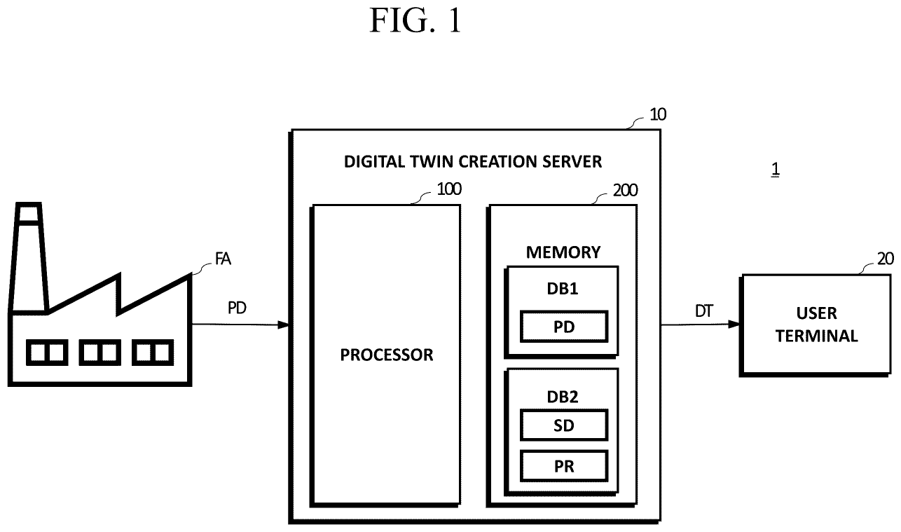

FIG. 1 is a block diagram of a digital twin creation system according to an exemplary embodiment of the present disclosure.

Referring to FIG. 1, a digital twin creation system 1 may create a digital twin DT on the basis of plant data PD sensed from a target facility FA and provide the digital twin DT to a user terminal 20. To this end, the digital twin creation system 1 may include a digital twin creation server 10 and the user terminal 20.

Components of the digital twin creation system 1 may be connected by wire or wirelessly to communicate with each other. When connected by wire, the components of the digital twin creation system 1 may perform serial communication. When connected wirelessly, the components of the digital twin creation system 1 may communicate with each other using a wireless communication network, which includes, but is not limited to, a local area network (LAN), a wide area network (WAN), the Internet (the World Wide Web (WWW)), a wired/wireless data communication network, a telephone network, a wired/wireless television communication network, a 3^{rd} Generation (3G) network, a 4^{th} Generation (4G) network, a 5^{th} Generation (5G) network, a 3^{rd} Generation Partnership Project (3GPP) network, a 5^{th} Generation Partnership Project (5GPP) network, a Long Term Evolution (LTE) network, a World Interoperability for Microwave Access (WIMAX) network, a Wi-Fi network, an Internet network, a wireless LAN, a personal area network (PAN), a radio frequency (RF) network, a Bluetooth network, a near-field communication (NFC) network, a satellite broadcast network, an analog broadcast network, a digital multimedia broadcasting (DMB) network, and the like.

The target facility FA is a facility which is a target of the digital twin DT. For example, the target facility FA may include a factory, machinery, equipment, objects, etc., for performing a chemical process. In the target facility FA, sensors (e.g., a temperature sensor, a pressure sensor, a flow sensor, etc.) for sensing various characteristics of the target facility FA may be installed, and the sensors may generate the plant data PD by measuring various characteristics (e.g., a temperature of a specific part of the facility, an internal pressure of the facility, and a rate of flow in the facility) of the target facility FA. Also, according to embodiments, the plant data PD may further include not only data measured by the sensors but also data (e.g., a concentration, the number of moles, etc., of a material input into the facility) input by an operator of the target facility FA.

The digital twin creation server 10 may include a variety of components used for creating the digital twin DT. The digital twin creation server 10 may be implemented by a server (including a cloud server that is run online) or various terminal devices including a personal computer (PC), a cellular phone, a smartphone, a laptop, a navigation device, a personal communication system (PCS) terminal, a Global System for Mobile Communications (GSM) device, a personal digital cellular (PDC) terminal, a personal handy-phone system (PHS) terminal, a personal digital assistant (PDA) terminal, an International Mobile Telecommunication (IMT)-2000 terminal, a code division multiple access (CDMA)-2000 terminal, a wideband code division multiple access (W-CDMA) terminal, a WiBro terminal, a smartpad, and a tablet PC.

The digital twin creation server 10 may include a processor 100 and a memory 200. The processor 100 may perform a variety of operations to create the digital twin DT using a first database DB1 and a second database DB2 stored in the memory 200. The memory 200 may store various kinds of data (e.g., the plant data PD, prediction data SD, and parameters PR) required for creating the digital twin DT. As an example, the processor 100 may include at least one of a central processing unit (CPU), a graphics processing unit (GPU), a neural processing unit (NPU), a random access memory (RAM), a read-only memory (ROM), a system bus, and an application processor, and the memory 200 may include a non-volatile memory, a volatile memory, a flash memory, a hard disk drive (HDD), a solid state drive (SSD), or the like.

In this specification, operations of the digital twin creation server 10 or components therein may be operations performed by the processor 100 on the basis of a computer program including at least one instruction stored in the memory 200.

The processor 100 may receive the plant data PD from the target facility FA and store the received plant data PD in the first database DB1 of the memory 200. Also, the processor 100 may generate the prediction data SD by inputting the plant data PD into a prediction model to which the parameters PR are applied. The processor 100 may store the prediction data SD and the parameters PR in the second database DB2. According to the exemplary embodiment, the first database DB1 and the second database DB2 may be separately managed and stored in different areas (e.g., at different addresses) of the memory 200.

According to the exemplary embodiment of the present disclosure, the processor 100 may update the parameters PR on the basis of the plant data PD. Accordingly, changes in the parameters PR due to changes in the plant data PD may be reflected in real time in the prediction model, and changes in the target facility FA may also be reflected in real time in the digital twin DT.

According to the exemplary embodiment of the present disclosure, the processor 100 may determine whether the plant data PD is in a steady state, and update the parameters PR using the plant data PD in a steady state. In this specification, a steady state means a state that a system or component ultimately reaches when external inputs to the system or component do not change (are not transient) and remain at constant values. Accordingly, changes in the parameters PR due to changes in the plant data PD may be reflected in real time in the prediction model, and changes in the target facility FA may also be reflected in real time in the digital twin DT.

The user terminal 20 may include a variety of components that are utilized to check or control various kinds of data of the target facility FA through the digital twin DT, and may be implemented by various terminal devices including a PC, a cellular phone, a smartphone, a laptop, a navigation device, a PCS terminal, a GSM device, a PDC terminal, a PHS terminal, a PDA terminal, an IMT-2000 terminal, a CDMA-2000 terminal, a W-CDMA terminal, a WiBro terminal, a smartpad, and a tablet PC.

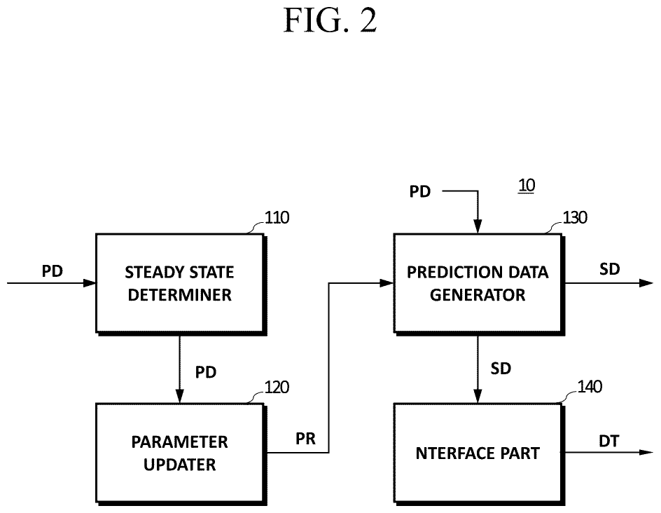

FIG. 2 is a block diagram showing a digital twin creation server according to an exemplary embodiment of the present disclosure.

Referring to FIG. 2, the digital twin creation server 10 may include a steady state determiner 110, a prediction data generator 130, a parameter updater 120, and an interface part 140. The steady state determiner 110, the prediction data generator 130, the parameter updater 120, and the interface part 140 may be software modules delimited by functions that are performed on the basis of the computer program stored in the memory 200 by the processor 100 included in the digital twin creation server 10, and operations performed by the steady state determiner 110, the prediction data generator 130, the parameter updater 120, and the interface part 140 may be performed through separate software modules and a plurality of pieces of hardware or one piece of hardware.

In the illustrated implementation, the memory 200 maintains a first database DB1 for raw/aggregated plant data (e.g., P2 means with timestamps) and a second database DB2 for derived artifacts such as the parameter vectors PR and the prediction data SD. The separation allows for independent retention policies (e.g., longer retention for PR/SD to support model validation) and enables low-latency reads by the prediction data generator 130. The processor 100 may execute the steady-state determination and parameter update asynchronously with respect to the P2 acquisition, thereby avoiding contention and ensuring that visualization and control tasks meet real-time constraints.

The steady state determiner 110 may receive the plant data PD and determine whether the plant data PD is in a steady state. As an example, the steady state determiner 110 may acquire the plant data PD by reading the plant data PD stored in the first database DB1. According to the exemplary embodiment, the steady state determiner 110 may receive a plurality of pieces of plant data PD corresponding to different time points and determine whether the plant data PD is in a steady state on the basis of whether a variance value of the plurality of pieces of plant data PD is a predetermined value or less. According to the exemplary embodiment of the present disclosure, it is possible to determine whether the plant data PD is in a steady state simply and accurately by determining whether the plant data PD is in a steady state on the basis of variance, and as a result, the parameters PR corresponding to the accurate plant data PD can be determined.

The parameter updater 120 may determine the parameters PR on the basis of the plant data PD in a steady state. According to the exemplary embodiment, the parameter updater 120 may determine the parameters PR by applying a mean value of the plurality of pieces of plant data PD to the prediction model. According to the exemplary embodiment of the present disclosure, when the mean value of the plant data PD is used to determine the parameters PR, the parameters PR can be updated to reflect a state of the target facility FA during a predetermined period, and the accurate state of the target facility FA can be reflected in the prediction model.

As an example, the parameter updater 120 may receive, as the plant data PD, pressure difference values, measured temperature values, and measured rate-of-flow values at a specific point of the target facility FA and obtain a reaction rate constant, the amount of coke, and a heat transfer coefficient as the parameters PR by applying the received pressure difference values, measured temperature values, and measured rate-of-flow values to predetermined formulae. The parameter updater 120 may store the acquired parameters PR in the second database DB2 of the memory 200.

When a window is classified as steady state, the parameter updater 120 computes a window mean of relevant plant data (e.g., temperature Tamb, flow rate F, pressure difference at a measured location) and obtains a parameter vector PR for the prediction model. In an exemplary chemical-process embodiment, PR includes at least one of a reaction rate constant (k0), a coke amount (Mcoke), and a heat-transfer coefficient (U). The parameter updater 120 may determine PR by solving or numerically minimizing mass-balance and energy-balance equations that relate the window mean inputs to process outputs as described herein (see, e.g., Equation (1)). The updated parameter vector PR is written to the second database DB2 together with a timestamp and the corresponding window identifier, enabling versioned replay of the digital twin for auditing and model-drift analysis.

If the steady-state gate is not satisfied for a prolonged period (e.g., due to frequent grade changes or start-up), the parameter updater 120 defers updates and continues to use the last valid parameter vector PR*, thereby preventing contamination of the prediction model by transient or noisy data.

The prediction data generator 130 may generate the prediction data SD by inputting the plant data PD stored in the first database DB1 into the prediction model to which the parameters PR determined by the parameter updater 120 are applied. The prediction data generator 130 may store the generated prediction data SD in the second database DB2 of the memory 200. As an example, the plant data PD received by the prediction data generator 130 may include a measured temperature value T_{amb} and a measured rate-of-flow value F at a specific point of the target facility FA, and the updated parameters PR may include a reaction rate constant k0, the amount of coke Mcoke, and a heat transfer coefficient U. When ΔP is a predicted pressure difference, T_{tube} is a temperature at an unmeasurable point, and Cmol1 and Cmol2 are the numbers of moles of compositions, the prediction data SD may be generated by a prediction model corresponding to Equation 1 below (in the following equations, r_{coke} is a coke generation rate, Ea is a constant, tₙ is a current time point, tₙ₋₁ is a previous time point, Δt=tₙ−tₙ₋₁, A_{tube} is the area of a tube installation, and Q is total calories).

$$\begin{matrix}{r}_{coke} = k [ C mol 1 ] [ C mol 2 ] \\ k = k 0 * exp ( - \frac{Ea}{{T}_{tube}} ) \\ {M}_{coke} ( {t}_{n} ) = {M}_{coke} ( {t}_{n - 1} ) + {r}_{coke} * Δ t \\ Δ P = f ( {A}_{tube} , F ) \\ {A}_{tube} = f ( {M}_{coke} ) \\ Q = U * ( T - {T}_{tube} ) * {A}_{tube}\end{matrix} \qquad [ Equation 1 ]$$

The prediction data generator 130 receives the current plant data PD (e.g., T_{amb} and F) and the updated parameters PR and evaluates the prediction model to produce prediction data SD. In the illustrated embodiment, SD includes at least one unmeasured variable such as a tube-wall temperature T_{tube}, a predicted pressure drop (ΔP), and composition mole numbers (Cmol1, Cmol2). The model may be evaluated in discrete time with step size Δt=tn−tn−1 and may incorporate accumulated terms such as a coke generation rate r_{coke} and total heat Q, as set forth in Equation (1). The generated prediction data SD is stored in the second database DB2 for subsequent visualization, control, and traceability.

The interface part 140 may reflect the prediction data SD in an interface to create the digital twin DT. As an example, the prediction data SD may include temperature information of an unmeasurable point, and the interface part 140 may create a digital twin by changing the color of the unmeasurable point on the basis of the temperature information included in the prediction data SD.

In certain embodiments, the interface part 140 not only updates a visualization of the digital twin DT but also provides a control interface to the target facility FA. The interface part 140 compares selected elements of the prediction data SD (for example, Ttube or ΔP) against predefined operating limits and safety limits maintained in the memory 200. When a violation or a projected deviation beyond a configured margin is detected, the interface part 140 generates a control command that, when executed by a controller of the target facility (e.g., PLC/DCS), actuates one or more physical actuators such as a valve, a heater, or a pump to adjust a process condition. The control command may encode a setpoint or a rate-of-change directive and may be transmitted over a wired or wireless industrial communication network. In one example, an over-temperature prediction for an unmeasured region triggers a staged decrease of heater power combined with an increase in coolant flow; after the variables return within a safe band, the interface part 140 automatically reverts to nominal setpoints. This closed-loop action integrates the prediction model into real-time plant operation, thereby improving safety and stability.

To enhance robustness, the interface part 140 may implement failsafe policies, including: (i) aborting transmission when integrity checks fail; (ii) clamping setpoints to equipment-specific bounds; and (iii) recording acknowledgements and outcomes of control actions in the second database DB2 to support audit and recovery.

According to an exemplary embodiment of the present disclosure, the digital twin creation server 10 updates the parameters PR of the prediction model on the basis of the plant data PD in a steady state and generates the prediction data SD on the basis of the updated parameters PR. Accordingly, information on the target facility FA in an accurate state can be reflected in the prediction model for creating a digital twin, and as a result, it is possible to create a digital twin that is synchronized with the target facility FA in real time.

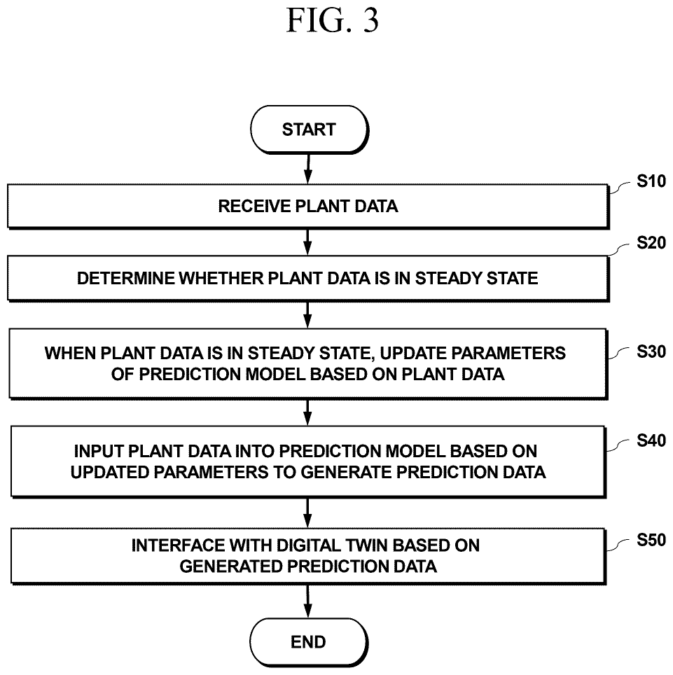

FIG. 3 is a flowchart showing a digital twin creation method according to an exemplary embodiment of the present disclosure.

Referring to FIG. 3, the digital twin creation server 10 may receive plant data PD from a target facility FA (S10) and determine whether the plant data is in a steady state (S20). According to the exemplary embodiment, the digital twin creation server 10 may determine whether the plant data PD is in a steady state on the basis of whether a variance value of the plant data PD is a predetermined value or less

When the plant data PD is in a steady state, the digital twin creation server 10 may update parameters PR of a prediction model on the basis of the plant data (S30). According to the exemplary embodiment, the digital twin creation server 10 may acquire the parameters PR from the prediction model using a mean value of the plant data PD.

The digital twin creation server 10 may generate prediction data SD by inputting the plant data PD into the prediction model based on the updated parameters PR (S40). The digital twin creation server 10 may create a digital twin by interfacing with the digital twin on the basis of the prediction data SD (S50).

With the digital twin creation method according to the technical spirit of the present disclosure, parameters PR are updated on the basis of plant data PD in a steady state such that a value of the plant data PR corresponding to the case where inputs from a target facility FA are in a steady state can be reflected in a prediction model. As a result, noise is removed, and accurate information on the target facility FA can be reflected in a digital twin in real time.

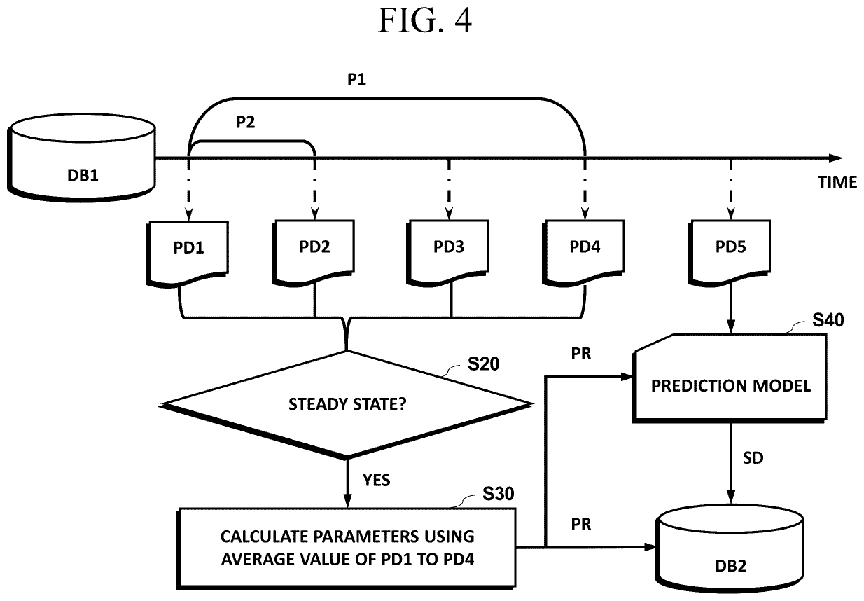

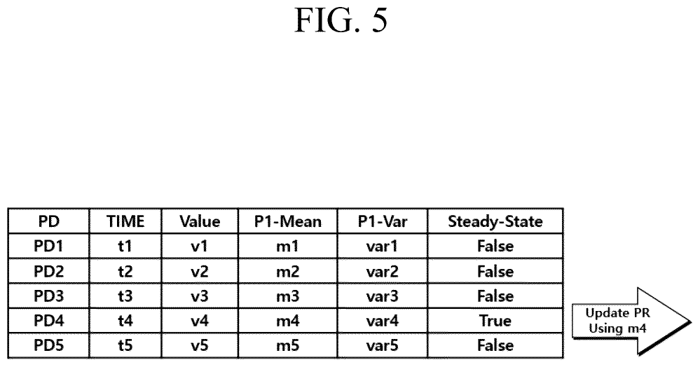

FIG. 4 is a diagram showing a digital twin creation method according to an exemplary embodiment of the present disclosure, and FIG. 5 is a table showing a steady state determination method according to an exemplary embodiment of the present disclosure.

Referring to FIG. 4, the digital twin creation server 10 may receive a plurality of pieces of plant data PD1, PD2, PD3, and PD4 acquired during a first period P1 from the first database DB1. In the example of FIG. 4, each of the first plant data PD1 to the fourth plant data PD4 may be plant data acquired from the target facility FA at a specific time point, and time points at which the first plant data PD1 to the fourth plant data PD4 are acquired may have intervals of a second period P2 in sequence.

The digital twin creation server 10 may determine whether the plurality of pieces of plant data PD1 to PD4 acquired during the first period P1 are in a steady state (S20). According to the exemplary embodiment, the digital twin creation server 10 may determine whether the plurality of pieces of plant data PD1 to PD4 are in a steady state by determining whether variance of the plurality of pieces of plant data PD1 to PD4 acquired during the first period P1 is a predetermined value or less. In the example of FIG. 4, the first period P1 is 3 times the second period P2, but embodiments of the present disclosure are not limited thereto. The first period P1 may be longer or shorter than 3 times the second period P2, and the number of pieces of plant data included in the first period P1 may vary. As an example, the first period P1 may be 3 hours, and the second period P2 may be 15 minutes.

When the plurality of pieces of plant data PD1 to PD4 are in a steady state, the digital twin creation server 10 may calculate parameters PR using a mean value of the plurality of pieces of plant data PD1 to PD4 (S30). The digital twin creation server 10 may store the calculated parameters PR in the second database DB2 and reflect the calculated parameters PR in a prediction model.

Referring to the example of FIG. 5, the digital twin creation server 10 may receive the first plant data PD1 corresponding to a first time point t1, the second plant data PD2 corresponding to a second time point t2, the third plant data PD3 corresponding to a third time point t3, the fourth plant data PD4 corresponding to a fourth time point t4, and fifth plant data PD5 corresponding to a fifth time point t5, and the first plant data PD1 to the fifth plant data PD5 may have, as data values, a first value v1, a second value v2, a third value v3, a fourth value v4, and a fifth value v5, respectively. When the plant data is measured temperatures, each of the first value v1 to the fifth value v5 may represent a temperature value.

The digital twin creation server 10 may calculate a first-period mean value P1-mean and a first-period variation value P1-Var. In the example of FIG. 4, the first period P1 includes 4 pieces of plant data. Accordingly, the first-period mean value P1-Mean corresponding to the fourth plant data PD4 may be a mean value of the first value v1 to the fourth value v4 corresponding to the first period P1 before the fourth plant data PD4, and the first-period variation value P1-Var may be a variation value of the first value v1 to the fourth value v4 corresponding to the first period P1 before the fourth plant data PD4.

The digital twin creation server 10 may determine whether the first-period variation value P1-Var is a predetermined value or less and determine whether the plant data is in a steady state on the basis of the determination result. As an example, the digital twin creation server 10 may determine whether a fourth variation value Var4 corresponding to the first plant data PD1 to the fourth plant data PD4 is the predetermined value or less. When the fourth variation value Var4 is the predetermined value or less, the digital twin creation server 10 may determine whether the plant data is in a steady state, and acquire parameters PR using a fourth mean value m4 that is the first-period mean value P1-Mean of the first plant data PD1 to the fourth plant data PD4.

Referring back to FIG. 4, the digital twin creation server 10 may generate prediction data SD by inputting fifth plant data PD5 into the prediction model in which the parameters PR are reflected (S40). The digital twin creation server 10 may store the prediction data SD in the second database DB2 and create a digital twin by utilizing the prediction data SD.

According to the exemplary embodiment of the present disclosure, whether the target facility FA is in a steady state can be easily determined by determining whether the plurality of pieces of plant data of the first period P1 are in a steady state using whether a variation value of the plurality of pieces of plant data is a predetermined value or less. Also, plant data in a steady state is utilized to update the parameters PR such that parameters with minimized noise can be reflected in the prediction model.

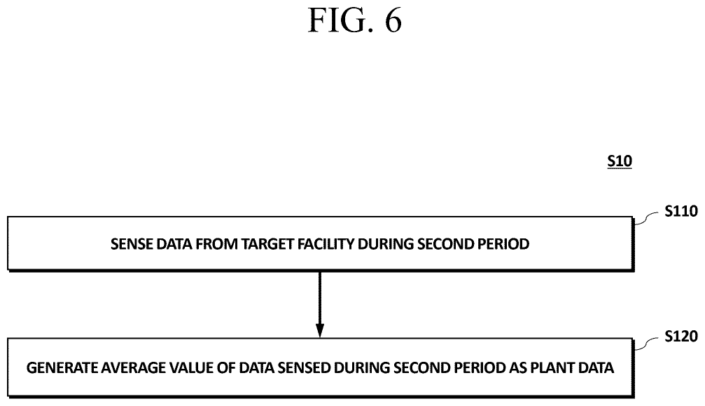

FIG. 6 is a flowchart showing the digital twin creation method according to the exemplary embodiment of the present disclosure. Specifically, FIG. 6 shows the operation S10 of receiving plant data in FIG. 3 in detail.

Referring to FIG. 6, the digital twin creation system 1 may sense the target facility FA during a second period (S110) and generate an average value of data sensed during the second period as plant data PD (S120).

According to the exemplary embodiment of the present disclosure, the digital twin creation system 1 does not directly generate results obtained by sensing the target facility FA as plant data but generates an average value of results obtained by sensing the target facility FA during a specific period as plant data. Therefore, it is possible to prevent plant data from having an incorrect value due to noise, and as a result, plant data to be reflected in a digital twin can be generated as accurate values.

According to an exemplary embodiment, the processor 100 implements a sliding-window steady-state gate. More specifically, plant data PD is acquired at a second period (P2) and buffered into a window of length first period (P1) where P1=N×P2 (N≥2). For each newly completed window, the steady state determiner 110 computes a variance value over the buffered samples and compares the variance with a sensor-specific threshold stored in the memory 200. When the variance is less than or equal to the threshold, the window is classified as steady state, and the parameter updater 120 is permitted to update model parameters; otherwise, parameter updates are withheld and previously validated parameters are retained. In some embodiments, a hysteresis policy is applied such that steady-state classification requires the variance condition to be satisfied for M consecutive windows (M≥2), which prevents chattering due to transient fluctuations.

To further reduce noise, the digital twin creation system 1 may, during each second period P2, compute and store in the first database DB1 the mean value of raw sensor readings collected within P2. The use of the P2-mean as the atomic “plant data” sample reduces the influence of high-frequency sensor spikes while preserving process dynamics that are relevant to parameter identification over P1.

By way of example and without limitation, consider P2=15 minutes and P1=3 hours (N=12). The steady state determiner 110 declares steady state only after the variance of 12 consecutive P2-means for a given sensor remains below the sensor's threshold for M=2 consecutive windows. Upon such declaration, the parameter updater 120 computes the window mean and updates PR={k0, Mcoke, U}. The prediction data generator 130 then evaluates the model to obtain Ttube and ΔP. If the interface part 140 detects that T_{tube} will exceed a safety limit within the next Δt, it sends a control command to decrease heater power by a predefined ramp and increase coolant flow for a hold period, after which normal operation is resumed. Throughout the sequence, the updated PR and the resulting SD are recorded in DB2, and the digital twin DT overlays the predicted Ttube distribution on AR2.

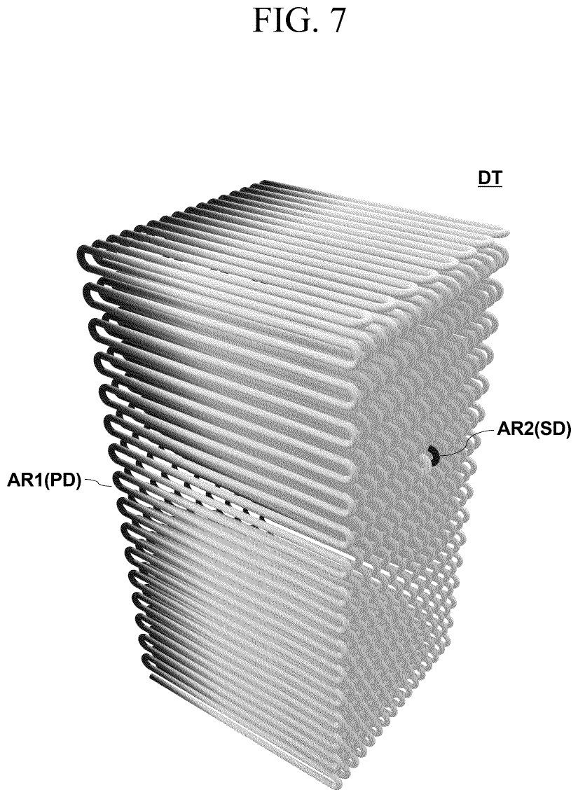

FIG. 7 is a view of a digital twin according to an exemplary embodiment of the present disclosure.

Referring to FIG. 7, a target facility may include a first area AR1 that is measurable by a sensor or the like, and a second area AR2 that is unmeasurable by a sensor or the like. The digital twin creation system 1 may generate plant data PD as a result of sensing the first area AR1 and update parameters depending on whether the sensed plant data is in a steady state. Also, the digital twin creation system 1 may generate prediction data SD on the basis of a prediction model of which the parameters have been updated and interfaces with the second area AR2 to correspond to the prediction data SD (e.g., changing the color of the second area AR2 to correspond to the prediction data), thereby creating a digital twin DT.

According to the exemplary embodiment of the present disclosure, since the digital twin creation system 1 adaptively changes parameters, information on the target facility can be reflected in the digital twin DT in real time, and as a result, the digital twin DT that matches the actual target facility can be created.

As shown in FIG. 7, the target facility may include a measurable first area AR1 and an unmeasurable second area AR2. The interface part 140 maps the prediction data SD to the digital twin DT by applying a visual overlay to AR2—e.g., color-coding Ttube across the geometry of AR2 or rendering a vector field for predicted composition gradients. The mapping function may use calibrated colormaps and threshold-based annotations (e.g., warning badges when a local value exceeds a limit), allowing an operator to visually localize process hotspots that are not directly instrumented. This visualization is updated at each second period P2 so that the DT remains synchronized with the target facility FA.

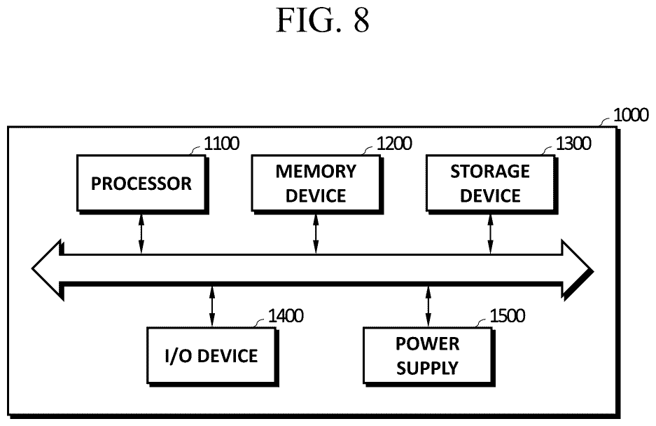

FIG. 8 is a block diagram showing a digital twin creation server according to an exemplary embodiment of the present disclosure.

Referring to FIG. 8, a digital twin creation server 1000 may include a processor 1100, a memory device 1200, a storage device 1300, an input/output (I/O) device 1400, and a power supply 1500. Meanwhile, although not shown in FIG. 8, the digital twin creation server 1000 may further include ports that may communicate with a video card, a sound card, a memory card, a Universal Serial Bus (USB) device, etc., or communicate with other electronic devices.

Like this, the processor 1100, the memory device 1200, the storage device 1300, the power supply 1500, and the I/O device 1400 included in the digital twin creation server 1000 may perform operations of the digital twin creation server 1000 according to exemplary embodiments based on the technical spirit of the present invention. Specifically, the operations of the digital twin creation server 1000 described above in FIGS. 1 to 7 may be operations performed by the processor 1100 on the basis of a computer program including at least one instruction stored in the memory device 1200 or the storage device 1300.

The processor 1100 may perform specific calculations or tasks. According to the exemplary embodiment, the processor 1100 may include at least one of a microprocessor, a CPU, a GPU, an NPU, a RAM, a ROM, a system bus, and an application processor. The processor 1100 may communicate with the memory device 1200, the storage device 1300, and the I/O device 1400 through a bus 1600 such as an address bus, a control bus, a data bus, and the like. According to the exemplary embodiment, the processor 1100 may also be connected to an expansion bus such as the peripheral component interconnect (PCI) bus.

The memory device 1200 may store data required for the digital twin creation server 1000 to operate. For example, the memory device 1200 may be implemented as a dynamic RAM (DRAM), a mobile DRAM, a static RAM (SRAM), a phase-change RAM (PRAM), a ferroelectric RAM (FRAM), a resistive RAM (RRAM), and/or a magnetoresistive RAM (MRAM). The storage device 1300 may include an SDD, an HDD, a compact disc (CD)-ROM, or the like. The memory device 1200 and the storage device 1300 may store a program for the digital twin creation method described above in FIGS. 1 to 7.

The I/O device 1400 may include an input device such as a keyboard, a keypad, a mouse, etc., and an output device such as a printer, a display, and the like. The power supply device 1500 may supply an operation voltage required for the digital twin creation server 1000 to operate.

According to the technical spirit of the present disclosure, parameters of a prediction model are updated on the basis of plant data in a steady state, and the updated parameters are utilized to generate prediction data. Therefore, changes in a target facility of which a digital twin has been created can be reflected in the prediction model in real time through the parameters, and as a result, the degree of synchronization of the digital twin with the target facility can increase.

While the embodiments above use variance as the steady-state criterion, additional filters (e.g., outlier rejection within the P1 window) may be applied in conjunction with the variance test to improve robustness without altering the decision rule. Moreover, the thresholds can be sensor-specific to reflect differences in sensor noise characteristics and installation locations within the target facility FA. The control interface of the interface part 140 may generate advisory messages instead of commands in installations where automatic actuation is restricted; in such cases, an operator may confirm a suggested setpoint change on the user terminal 20, after which the command is sent to the controller.

Exemplary embodiments have been disclosed in the drawings and specification. Although specific terms are used in this specification to describe the exemplary embodiments, these are only used for the purpose of describing the technical spirit of the present disclosure and are not used to limit the scope of the present disclosure described in the claims. Accordingly, those of ordinary skill in the art should understand that various modifications and other equivalent embodiments can be made based on the exemplary embodiments. Therefore, the technical scope of the present invention should be determined based on the following claims.

What is claimed is:

1. A method of creating a digital twin performed by at least one processor, the method comprising:
receiving, by the processor, plant data generated by sensing a target facility which is a target of a digital twin;
determining, by the processor, whether the plant data is in a steady state on the basis of the plant data;
when the plant data is in a steady state, updating, by the processor, parameters of a prediction model on the basis of the plant data;
inputting, by the processor, the plant data into the prediction model based on the updated parameters to generate prediction data; and
outputting, by the processor, the prediction data.

2. The method of claim 1, wherein the determining of whether the plant data is in a steady state comprises:
receiving a plurality of pieces of plant data that are sequentially measured over time during a first period;
calculating a variance value of the plurality of pieces of plant data;
determining whether the variance value is a predetermined value or less; and
when the variance value is the predetermined value or less, determining that the plurality of pieces of plant data are in a steady state.

3. The method of claim 2, wherein the updating of the parameters of the prediction model on the basis of the plant data comprises:
calculating a mean value of the plurality of pieces of plant data;
acquiring the parameters from the prediction model using the calculated mean value; and
applying the acquired parameters to the prediction model to update the parameters.

4. The method of claim 2, wherein the receiving of the plant data comprises receiving the plant data every second period, which is shorter than the first period.

5. The method of claim 4, wherein the updating of the parameters of the prediction model comprises:
collecting the plurality of pieces of plant data by collecting N (N is a natural number of 2 or more) pieces of the plant data, which correspond to the first period, acquired every second period;
calculating a mean value of the plurality of pieces of plant data;
acquiring the parameters from the prediction model using the calculated average value; and
updating the parameters by applying the acquired parameters to the prediction model.

6. The method of claim 1, further comprising creating, by the processor, the digital twin by applying an interface corresponding to the prediction data to the target facility.

7. A system for creating a digital twin including at least one processor, the system comprising:
a steady state determiner configured to determine whether plant data generated by sensing a target facility which is a target of a digital twin is in a steady state;
a parameter updater configured to acquire parameters by applying the plant data to a prediction model when the plant data is in a steady state, and apply the acquired parameters to the prediction model;
a prediction data generator configured to generate prediction data by inputting the plant data into the prediction model with the updated parameters; and
an interface part configured to create a digital twin by interfacing with the digital twin on the basis of the prediction data.

8. The system of claim 7, wherein the steady state determiner determines whether a plurality of pieces of plant data that are sequentially measured over time during a first period are in a steady state on the basis of whether a variance value of the plurality of pieces of plant data is a predetermined value or less.

9. The system of claim 7, wherein the parameter updater acquires the parameters from the prediction model using a mean value of the plurality of pieces of plant data.

10. A method of creating a digital twin performed by at least one processor, the method comprising:
receiving, by the processor, plant data generated by sensing a target facility which is a target of a digital twin, the plant data being acquired at a second period that is shorter than a first period;
determining, by the processor, whether the plant data is in a steady state based on the plant data, the determining comprising:
receiving a plurality of pieces of the plant data that are sequentially measured over the first period,
computing a variance value of the plurality of pieces of the plant data,
determining whether the variance value is less than or equal to a predetermined value, and
in response to the variance value being less than or equal to the predetermined value, determining that the plurality of pieces of the plant data are in the steady state;
when the plant data is in the steady state, updating, by the processor, parameters of a prediction model based on the plant data, the updating comprising:
calculating a mean value of the plurality of pieces of the plant data,
acquiring parameters from the prediction model using the calculated mean value, and
applying the acquired parameters to the prediction model;
generating, by the processor, prediction data by inputting the plant data into the prediction model based on the updated parameters;
outputting, by the processor, the prediction data; and
creating, by the processor, the digital twin by applying an interface corresponding to the prediction data to a digital representation of the target facility.
